(19) United States
(12) Patent Application Publication
(10) Pub. No.: US 2023/0079520 A1
(43) Pub. Date: Mar. 16, 2023

(54) SUBSTRATE GRINDING DEVICE AND SUBSTRATE GRINDING METHOD

(71) Applicant: OKAMOTO MACHINE TOOL WORKS, LTD., Gunma (JP)

(72) Inventors: Satoru IDE, Gunma (JP); Takahiko MITSUI, Gunma (JP); Hiroshi YAMAMOTO, Gunma (JP)

(21) Appl. No.: 17/877,366

(22) Filed: Jul. 29, 2022

(30) Foreign Application Priority Data
Sep. 14, 2021 (JP) 2021-149742

(51) Int. Cl. B24B 27/00; B24B 7/22; B24B 7/04; B24B 41/06; B24D 13/14

(52) U.S. Cl. CPC B24B 27/0076; B24B 7/228; B24B 7/04; B24B 41/06; B24D 13/142

(57) ABSTRACT

Provided is a substrate grinding device including: a work table; a first grinding wheel; and a second grinding wheel, wherein the work table is configured to rotate while sucking and holding a substrate, the first grinding wheel and the second grinding wheel are cup wheel type wheels, and provided at positions where the first grinding wheel and the second grinding wheel can be simultaneously in contact with the substrate rotating, the first grinding wheel and the second grinding wheel being configured to grind the substrate rotating, while rotating, and the work table is configured to be able to move a rotation center of the substrate from a first grinding position within a grinding range of the first grinding wheel to a second grinding position within a grinding range of the second grinding wheel.

### CROSS-REFERENCE TO RELATED APPLICATION

This application claims priority from Japanese Patent Application No. 2021-149742 filed with the Japan Patent Office on Sep. 14, 2021, the entire content of which is hereby incorporated by reference.

### BACKGROUND

### 1. Technical Field

The present disclosure relates to a substrate grinding device and a substrate grinding method.

### 2. Related Art

In recent years, a size of a substrate that is an object of grinding has been increasing. As this type of large-sized substrate, for example, a wafer level package (WLP), a panel level package (PLP) that is a large-sized mounting substrate having a larger size than the WLP, and the like are known. Then, there is a demand for a technique for grinding this kind of large-sized substrate efficiently and with high accuracy.

JP-A-2020-040189 discloses a substrate grinding device used for grinding this type of large-sized substrate. The substrate grinding device disclosed in JP-A-2020-040189 includes a cup wheel type finish grinding wheel that, while rotating, grinds a rotating substrate held on a work table, and a cup wheel type rough grinding wheel that grinds the substrate while rotating in close proximity to the substrate simultaneously with the finish grinding wheel.

With such a configuration, it is possible to grind the large-sized mounting substrate such as a PLP having a large warp at the same time by the finish grinding wheel and the rough grinding wheel without conveying the large-sized mounting substrate by a turntable or the like. Therefore, it is possible to grind the large-sized substrate with high accuracy in a short time without increasing a size of the substrate grinding device.

### SUMMARY

A substrate grinding device according to an embodiment of the present disclosure includes: a work table; a first grinding wheel; and a second grinding wheel. The work table is configured to rotate while sucking and holding a substrate. The first grinding wheel and the second grinding wheel are cup wheel type wheels, and provided at positions where the first grinding wheel and the second grinding wheel can be simultaneously in contact with the substrate rotating, the first grinding wheel and the second grinding wheel being configured to grind the substrate rotating, while rotating. The work table is configured to be able to move a rotation center of the substrate from a first grinding position within a grinding range of the first grinding wheel to a second grinding position within a grinding range of the second grinding wheel.

### BRIEF DESCRIPTION OF THE DRAWINGS

FIG. 1 is a plan view illustrating an outline of a substrate grinding device according to an embodiment of the present disclosure;

FIG. 2 is a plan view illustrating the vicinity of a grinding stage at a first grinding position of the substrate grinding device according to the embodiment of the present disclosure;

FIG. 3 is a vertical cross-sectional view schematically illustrating the vicinity of the grinding stage at the first grinding position of the substrate grinding device according to the embodiment of the present disclosure;

FIG. 4 is a plan view illustrating the vicinity of the grinding stage at a second grinding position of the substrate grinding device according to the embodiment of the present disclosure;

FIG. 5 is a vertical cross-sectional view schematically illustrating the vicinity of the grinding stage at the second grinding position of the substrate grinding device according to the embodiment of the present disclosure;

FIG. 6 is a vertical cross-sectional view schematically illustrating the vicinity of a rotation center of a substrate in a rough grinding step of the substrate grinding device according to the embodiment of the present disclosure;

FIG. 7 is a vertical cross-sectional view schematically illustrating the vicinity of the rotation center of the substrate in a finish grinding step of the substrate grinding device according to the embodiment of the present disclosure;

FIG. 8 is a vertical cross-sectional view schematically illustrating the vicinity of the rotation center of the substrate in a modification of a second grinding step of the substrate grinding device according to the embodiment of the present disclosure; and

FIG. 9 is a vertical cross-sectional view schematically illustrating the vicinity of the rotation center of the substrate in the modification of the second grinding step of the substrate grinding device according to the embodiment of the present disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

However, the above-mentioned substrate grinding device according to the related art has some points to be improved in order to perform efficient grinding.

The substrate grinding device according to the related art disclosed in JP-A-2020-040189 can grind a substrate at the same time by a finish grinding wheel and a rough grinding wheel without moving the substrate.

However, in the substrate grinding device of JP-A-2020-040189, since the rough grinding wheel is provided at a position where a grinding range of the rough grinding wheel does not pass through a rotation center of the substrate, the vicinity of the rotation center of the substrate cannot be ground. That is, even if rough grinding is performed, an unground protrusion remains in the vicinity of the rotation center of the substrate. Therefore, the protrusion left in the vicinity of the rotation center of the substrate is ground only by the finish grinding wheel.

Therefore, the substrate grinding device according to the related art has a problem that an amount of grinding by the finish grinding wheel is large and it is difficult to shorten grinding time. Further, as an amount of wear of the finish grinding wheel increases, the number of times the finish grinding wheel is replaced also increases, and thus there is a problem that production cost of the substrate is high.

In particular, in recent years, it has been required to process a surface of a large-sized mounting substrate such as a PLP with higher accuracy. Therefore, as the finish grinding wheel, it is required to use a grinding wheel having a smaller abrasive grain size than before.

As described above, in the substrate grinding device according to the related art, it is required to grind the protrusion in the vicinity of the rotation center of the substrate by the finish grinding wheel. Therefore, when selecting the finish grinding wheel, it is required to select a finish grinding wheel capable of grinding the protrusion. This is a constraint when choosing the finish grinding wheel.

In order to grind a surface to be processed of the substrate with high accuracy, it may be required to use, for example, a grinding wheel having a large grain size number (for example, a grinding wheel having a grain size number of #8000) as the finish grinding wheel. In that case, in the substrate grinding device according to the related art, there is a problem that it takes time to grind the protrusion in the vicinity of the rotation center. Further, since the grinding wheel having a large grain size number, that is, the grinding wheel having a small abrasive grain size, wears heavily, there is a problem that it is difficult to actually use it as the finish grinding wheel.

The present disclosure has been made in view of the above circumstances, and an object of the present disclosure is to provide a substrate grinding device and a substrate grinding method capable of grinding a large-sized substrate efficiently and with high accuracy.

A substrate grinding device according to the present disclosure includes: a work table; a first grinding wheel; and a second grinding wheel. The work table is configured to rotate while sucking and holding a substrate. The first grinding wheel and the second grinding wheel are cup wheel type wheels, and provided at positions where the first grinding wheel and the second grinding wheel can be simultaneously in contact with the substrate rotating, the first grinding wheel and the second grinding wheel being configured to grind the substrate rotating, while rotating. The work table is configured to be able to move a rotation center of the substrate from a first grinding position within a grinding range of the first grinding wheel to a second grinding position within a grinding range of the second grinding wheel.

Moreover, a substrate grinding method according to the present disclosure includes: sucking a substrate on a rotatable work table; moving the work table holding the substrate so that a rotation center of the substrate is located below a cup wheel type first grinding wheel and a cup wheel type second grinding wheel and at a first grinding position within a grinding range of the first grinding wheel; grinding the substrate while rotating the work table, rotating the substrate held on the work table, and rotating the first grinding wheel, in a state where the rotation center of the substrate is located at the first grinding position; moving the work table holding the substrate so that the rotation center of the substrate is located below the first grinding wheel and the second grinding wheel and at a second grinding position within a grinding range of the second grinding wheel, after performing grinding by the first grinding wheel; and grinding the substrate while rotating the work table, rotating the substrate held on the work table, and rotating the second grinding wheel, in a state where the rotation center of the substrate is located at the second grinding position.

The substrate grinding device of the present disclosure has the cup wheel type first grinding wheel and second grinding wheel that, while rotating, grind the rotating substrate held on the work table. The first grinding wheel and the second grinding wheel are provided at the positions where they can simultaneously contact the rotating substrate. The work table is configured such that the rotation center of the substrate can be moved from the first grinding position within the grinding range of the first grinding wheel to the second grinding position within the grinding range of the second grinding wheel. With such a configuration, it is possible to grind the substrate efficiently and with high accuracy by appropriately setting both the first grinding wheel and the second grinding wheel. For example, the first grinding wheel is used as the rough grinding wheel, the second grinding wheel is used as the finish grinding wheel, and steps from rough grinding to finish grinding can be efficiently performed.

Further, the first grinding wheel and the second grinding wheel are provided at the positions where they can contact the rotating substrate at the same time. Therefore, it is easy to move the substrate from the first grinding position to the second grinding position. Specifically, unlike a conventional general substrate grinding device, it is not necessary to provide a rough grinding position and a finish grinding position at separate positions and convey the substrate by transferring the substrate on the work table that moves to each separate position. Further, it is not necessary to provide a large turntable or the like on which a plurality of work tables are placed. Therefore, the substrate grinding device of the present disclosure can reduce footprint of the device and grind the large-sized mounting substrate such as the PLP efficiently and with high accuracy.

Moreover, the substrate grinding device according to the present disclosure may be configured such that: grinding of the substrate by the first grinding wheel is performed in a state where the rotation center of the substrate is located at the first grinding position; and grinding of the substrate by the second grinding wheel is performed in a state where the rotation center of the substrate is located at the second grinding position.

Thus, when the rotation center of the substrate is located at the first grinding position, the entire area of the surface to be processed including the vicinity of the rotation center of the substrate can be ground by the first grinding wheel, and when the rotation center of the substrate is located at the second grinding position, the entire area of the surface to be processed including the vicinity of the rotation center of the substrate can be ground by the second grinding wheel. Therefore, the surface to be processed of the substrate can be ground efficiently and with high accuracy by effectively utilizing the first grinding wheel and the second grinding wheel.

Specifically, the first grinding wheel is the rough grinding wheel having a large abrasive grain size, the second grinding wheel is the finish grinding wheel having a small abrasive grain size, and it is possible to roughly grind the entire area of the surface to be processed of the substrate by the first grinding wheel, and then to finish grind the entire area of the surface to be processed of the substrate by the second grinding wheel.

That is, by efficient rough grinding, the entire area of the surface to be processed of the substrate is flattened without leaving the unground protrusion in the vicinity of the rotation center of the substrate, and then finish grinding can be performed. The second grinding wheel for performing finish grinding does not need to grind the protrusion left in the vicinity of the rotation center of the substrate as in the substrate grinding device according to the related art. Therefore, it is possible to finish the surface to be processed of the substrate with high accuracy by short-time grinding using the finish grinding wheel having a smaller abrasive grain size than that of the related art.

Further, since the second grinding wheel does not need to grind the protrusion in the vicinity of the rotation center of the substrate, the amount of wear of the second grinding wheel can be reduced to a small amount. Therefore, usage of the second grinding wheel can be reduced, and the production cost of the substrate can be reduced.

Moreover, the substrate grinding device according to the present disclosure may be configured to be able to grind the substrate simultaneously by the first grinding wheel and the second grinding wheel in a state where the rotation center of the substrate is located at the second grinding position. Thus, for example, grinding is performed simultaneously using the first grinding wheel having a large abrasive grain size for rough grinding and the second grinding wheel having a small abrasive grain size for finish grinding, so that efficiency of grinding can be improved.

Moreover, the substrate grinding method according to the present disclosure includes: sucking the substrate on the rotatable work table; moving the work table holding the substrate so that the rotation center of the substrate is located below the cup wheel type first grinding wheel and the cup wheel type second grinding wheel and at the first grinding position within the grinding range of the first grinding wheel; grinding the substrate while rotating the work table, rotating the substrate held on the work table, and rotating the first grinding wheel, in the state where the rotation center of the substrate is located at the first grinding position; moving the work table holding the substrate so that the rotation center of the substrate is located below the first grinding wheel and the second grinding wheel and at the second grinding position within the grinding range of the second grinding wheel, after performing grinding by the first grinding wheel; and grinding the substrate while rotating the work table, rotating the substrate held on the work table, and rotating the second grinding wheel, in the state where the rotation center of the substrate is located at the second grinding position. Thus, the large-sized mounting substrate such as the PLP can be ground efficiently and with high accuracy.

Moreover, the substrate grinding method according to the present disclosure may include: performing grinding by the first grinding wheel, and then moving the work table so that the rotation center of the substrate is located below the first grinding wheel and the second grinding wheel and at the second grinding position within the grinding range of the second grinding wheel; subsequently grinding the substrate simultaneously by the first grinding wheel and the second grinding wheel while rotating the work table, rotating the substrate held on the work table, and simultaneously rotating the first grinding wheel and the second grinding wheel, in the state where the rotation center of the substrate is located at the second grinding position; and then further grinding the substrate by the second grinding wheel with the first grinding wheel separated from the substrate. Thus, for example, between a rough grinding step using the first grinding wheel having a large abrasive grain size and a finish grinding step using the second grinding wheel having a small abrasive grain size, the grinding simultaneously using the first grinding wheel and the second grinding wheel can be performed, and the efficiency of grinding can be improved.

Hereinafter, the substrate grinding device according to an embodiment of the present disclosure will be described in detail with reference to the drawings.

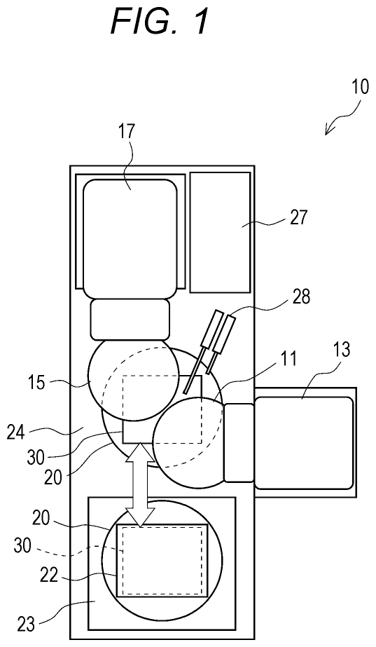

FIG. 1 is a plan view illustrating an outline of a substrate grinding device 10 according to the embodiment of the present disclosure.

As illustrated in FIG. 1, the substrate grinding device 10 is a device for grinding or polishing a substrate 30.

The substrate 30 to be processed by the substrate grinding device 10 may be, for example, a large-area mounting substrate such as the PLP, a package substrate, another laminated substrate, a semiconductor substrate, or a substrate for an element such as a capacitor. The substrate grinding device 10 grinds or polishes a resin layer, a copper electrode, a semiconductor element, or the like constituting the substrate 30 from a main surface of the substrate 30 with high accuracy, and even a large-area substrate 30 with warpage can be efficiently processed.

The substrate grinding device 10 includes a standby stage 23 for providing the substrate 30 to be processed, a grinding stage 24 for performing grinding of the substrate 30, a work table 20 for holding the substrate 30, and a rough grinding wheel 11 which is the first grinding wheel, and a finish grinding wheel 15 which is the second grinding wheel.

The standby stage 23 is a stage for fixing the substrate 30 to be processed to the work table 20 before grinding and removing the substrate 30 by releasing fixing of the substrate 30 to the work table 20 after grinding.

Above the standby stage 23, an attachment housing 22 for allowing a vacuum chuck of the work table 20 to suck the substrate 30 is provided. On the standby stage 23, the substrate 30 placed on an upper surface of the work table 20 is sandwiched between the attachment housing 22 descending from above and the work table 20 below, to be fixed to the work table 20 by vacuum suction using the vacuum chuck. After the substrate 30 is fixed to the work table 20, the attachment housing 22 rises away from the substrate 30.

The work table 20 is a table that rotates while holding the substrate 30 in the grinding step, and is provided so that the substrate 30 can be conveyed by moving substantially horizontally between the standby stage 23 and the grinding stage 24.

Specifically, after the substrate 30 is sucked on the upper surface of the work table 20 on the standby stage 23, the work table 20 moves to a predetermined position of the grinding stage 24 and rotates while holding the substrate 30. After grinding of the substrate 30 is completed, the work table 20 moves to a predetermined position of the standby stage 23.

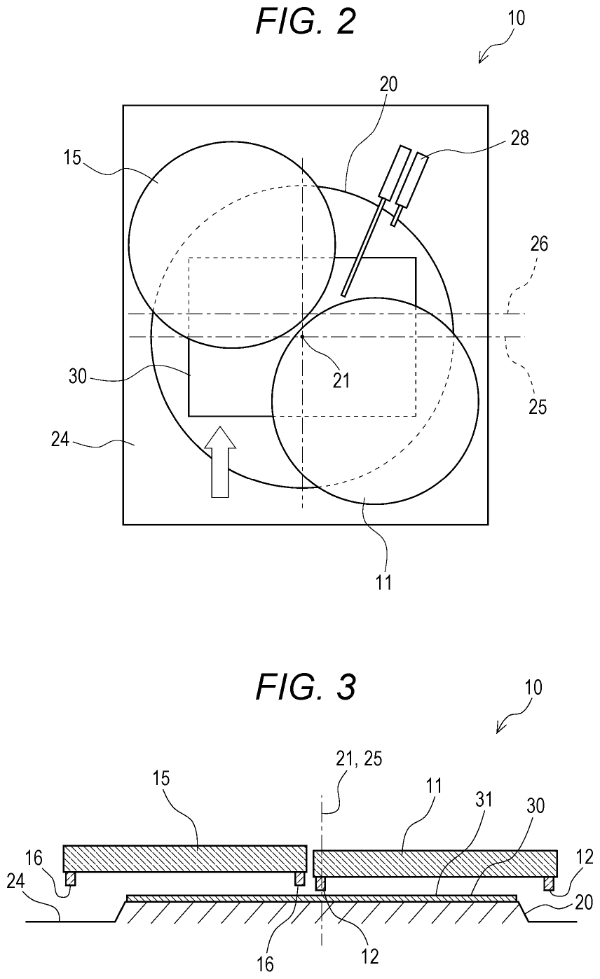

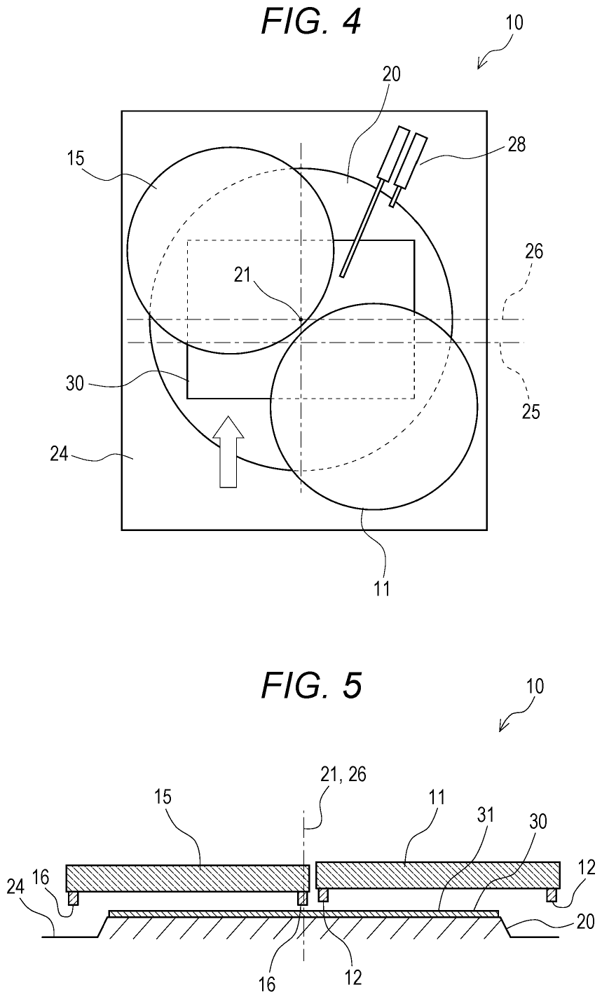

Note that a rotation center 21 of the substrate 30 can be moved by the work table 20 from a first grinding position 25 (see FIG. 2) within the grinding range of the rough grinding wheel 11 to a second grinding position 26 (see FIG. 4) within the grinding range of the finish grinding wheel 15.

The grinding stage 24 is a position for performing the grinding step of the substrate 30. The substrate 30 sucked on the upper surface of the work table 20 is conveyed to the grinding stage 24 together with the work table 20, and the grinding step of the substrate 30 is performed by the rough grinding wheel 11 and the finish grinding wheel 15.

The rough grinding wheel 11 is a cup wheel type grinding wheel that grinds the substrate 30 while rotating, and is supported by a rough grinding column 13 so as to be movable in an up-down direction. The rough grinding wheel 11 is provided above the work table 20 and the substrate 30, which have been conveyed to the grinding stage 24.

The finish grinding wheel 15 is a cup wheel type grinding wheel that grinds the substrate 30 while rotating, and is supported by a finish grinding column 17 so as to be movable in the up-down direction. The finish grinding wheel 15 is provided above the work table 20 and the substrate 30, which have been conveyed to the grinding stage 24.

The grinding stage 24 is provided with a sizing device 28. The sizing device 28 is a device that accurately detects the position of an upper surface 31 of the substrate 30 and measures processing dimensions of the substrate 30, in order to grind the substrate 30 with high accuracy.

The substrate grinding device 10 is provided with a control panel 27. The control panel 27 has, for example, an input unit for inputting various information, a monitor for displaying various information, an arithmetic unit for performing various calculations, and the like. The control panel 27 performs various calculations based on the input information, and monitors and controls processing of the entire substrate grinding device 10.

Further, the substrate grinding device 10 may be provided with a cleaning solution spray device (not illustrated) for cleaning the rough grinding wheel 11 and the finish grinding wheel 15. The cleaning solution spray device has a spray nozzle for spraying cleaning solution on the rough grinding wheel 11 and a spray nozzle for spraying the cleaning solution on the finish grinding wheel 15.

From the spray nozzle, for example, the cleaning solution is sprayed at a pressure of 3 MPa to 17 MPa in the vicinity of wheel cutting edges 12 and 16 (see FIG. 3) of the rough grinding wheel 11 and the finish grinding wheel 15, away from the substrate 30. Thus, in the grinding step, the shavings adhering to the rough grinding wheel 11 and the finish grinding wheel 15 can be washed away, and the substrate 30 can be ground with high accuracy.

FIG. 2 is a plan view illustrating the vicinity of the grinding stage 24 at the first grinding position 25 of the substrate grinding device 10. FIG. 3 is a vertical cross-sectional view schematically illustrating the vicinity of the grinding stage 24 at the first grinding position 25.

As illustrated in FIGS. 2 and 3, the rough grinding wheel 11 and the finish grinding wheel 15 are provided at positions where they can simultaneously contact the upper surface 31 of the rotating substrate 30 in the grinding step. Specifically, during the grinding step, the rough grinding wheel 11 is provided above the substrate 30 at a position where the rough grinding wheel 11 can contact the upper surface 31 of the substrate 30 when lowered. The finish grinding wheel 15 is also provided above the substrate 30 at a position where the finish grinding wheel 15 can contact the upper surface 31 of the substrate 30 when lowered.

The first grinding position 25 is a position of the substrate 30 on which a first grinding step described below is performed. Note that in FIG. 2, the first grinding position 25 indicates a position of the rotation center 21 of the substrate 30 in a horizontal feed direction when the first grinding step is performed. Note that the position in the horizontal feed direction is a position in a direction of an arrow in FIG. 2. Further, in FIG. 2, the second grinding position 26 indicates the position of the rotation center 21 of the substrate 30 in the horizontal feed direction when a second grinding step described below is performed.

At the first grinding position 25 of the grinding stage 24, the rough grinding wheel 11 and the finish grinding wheel 15 for grinding the substrate 30 are provided side by side above the substrate 30.

A diameter of the grinding range of the rough grinding wheel 11 is larger than a radius of the work table 20. The rough grinding wheel 11 is provided at a position where the grinding range passes through the rotation center 21 of the substrate 30. Thus, the rough grinding wheel 11 can roughly grind the entire area of the upper surface 31 which is the surface to be processed of the substrate 30.

The rough grinding wheel 11 mainly performs rough grinding of the substrate 30, and the finish grinding wheel 15 mainly performs finish grinding of the substrate 30. Therefore, the abrasive grain size of the finish grinding wheel 15 is smaller than that of the rough grinding wheel 11. The larger a grain size number is, the smaller the abrasive grain size is, in other words, the grain size number of the finish grinding wheel 15 is larger than that of the rough grinding wheel 11.

Further, a diameter of the finish grinding wheel 15 may be substantially the same as a diameter of the rough grinding wheel 11.

A diameter of the grinding range of the finish grinding wheel 15 is larger than the radius of the work table 20. The finish grinding wheel 15 is provided at a position close to the rotation center 21 of the substrate 30 and not in contact with the rough grinding wheel 11.

FIG. 4 is a plan view illustrating the vicinity of the grinding stage 24 at the second grinding position 26 of the substrate grinding device 10. FIG. 5 is a vertical cross-sectional view schematically illustrating the vicinity of the grinding stage 24 at the second grinding position 26.

As illustrated in FIGS. 4 and 5, the second grinding position 26 is a position of the substrate 30 on which the second grinding step described below is performed. Note that in FIG. 4, the first grinding position 25 and the second grinding position 26 indicate the positions of the rotation center 21 of the substrate 30 in the horizontal feed direction. Note that the position in the horizontal feed direction is a position in a direction of an arrow in FIG. 4.

As described above, the work table 20 holding the substrate 30 is provided so that the rotation center 21 of the substrate 30 can be moved from the first grinding position 25 to the second grinding position 26 (the position of the rotation center 21 of the substrate 30 can be adjusted).

In FIG. 4, the rough grinding wheel 11 is provided at a position close to the rotation center 21 of the substrate 30 and not in contact with the finish grinding wheel 15.

The finish grinding wheel 15 is provided at the position where the grinding range passes through the rotation center 21 of the substrate 30. Thus, the finish grinding wheel 15 can finish-grind the entire area of the upper surface 31 which is the surface to be processed of the substrate 30 with high accuracy.

That is, when the rotation center 21 of the substrate 30 is located at the first grinding position 25, the substrate grinding device 10 can grind, by the rough grinding wheel 11, the entire area of the surface to be processed including the vicinity of the rotation center 21 of the substrate 30. Further, when the rotation center 21 of the substrate 30 is located at the second grinding position 26, the substrate grinding device 10 can grind, by the finish grinding wheel 15 with high accuracy, the entire area of the surface to be processed including the vicinity of the rotation center 21 of the substrate 30.

Specifically, the first grinding wheel is the rough grinding wheel 11 having a large abrasive grain size, the second grinding wheel is the finish grinding wheel 15 having a small abrasive grain size, and it is possible to roughly grind the entire area of the surface to be processed of the substrate 30 by the first grinding wheel, and then to finish grind the entire area of the surface to be processed of the substrate 30 by the second grinding wheel.

As described above, the substrate grinding device 10 can grind the substrate 30 efficiently and with high accuracy by appropriately setting both the first grinding wheel and the second grinding wheel.

Further, the rough grinding wheel 11 and the finish grinding wheel 15 are provided at positions where they can simultaneously contact the rotating substrate 30. Further, the rough grinding wheel 11 and the finish grinding wheel 15 are provided at positions close to each other. The first grinding position 25 (rotation center 21 of the substrate 30 in FIG. 2) is located within the grinding range of the rough grinding wheel 11, and the second grinding position 26 (rotation center 21 of the substrate 30 in FIG. 4) is located within the grinding range of the finish grinding wheel 15. Since the rough grinding wheel 11 and the finish grinding wheel 15 are provided at positions close to each other, the rotation center 21 of the substrate 30 can be easily moved from the first grinding position 25 to the second grinding position 26.

In a conventional general substrate grinding device, a table installation equipment for rough grinding and a table installation equipment for finish grinding are separately provided at separate positions, and work tables for transporting the substrate 30 are respectively provided on the table installation equipments. Therefore, when the substrate 30 is conveyed from the table installation equipment for rough grinding to the table installation equipment for finish grinding, it is necessary to transfer the substrate 30 from a work table for rough grinding to a work table for finish grinding. In the substrate grinding device 10, it is not necessary to transfer the substrate 30 to another work table separately provided for each table installation equipment, to convey the substrate 30.

That is, the substrate grinding device 10 can continuously perform rough grinding and finish grinding without transferring the substrate 30 sucked and held on the work table 20 to another work table. Therefore, the time required for conveyance can be significantly reduced, and the production efficiency can be improved. Further, since there is no problem such as warpage due to transfer of the substrate 30, it is possible to form a flat surface efficiently and with high accuracy on the surface to be processed of the substrate 30.

Further, it is not necessary to provide devices corresponding to two steps of rough grinding and finish grinding at separate positions. Furthermore, it is not necessary to provide a large turntable or the like on which a plurality of work tables are placed. Therefore, the footprint of the substrate grinding device 10, that is, the occupied area can be reduced, and the large-sized substrate 30 can be efficiently ground. Therefore, a small-sized high-performance substrate grinding device 10 that can be used for the large-sized mounting substrate such as the PLP can be obtained.

For example, even if the substrate 30 to be processed is a large-sized mounting substrate such as a PLP having a large warp, it is possible to efficiently grind the substrate 30 by appropriately using the rough grinding wheel 11 and the finish grinding wheel 15 without conveying the work table 20 by providing the turntable or the like. In this way, a highly accurate grinding step is achieved by the substrate grinding device 10 in a short time.

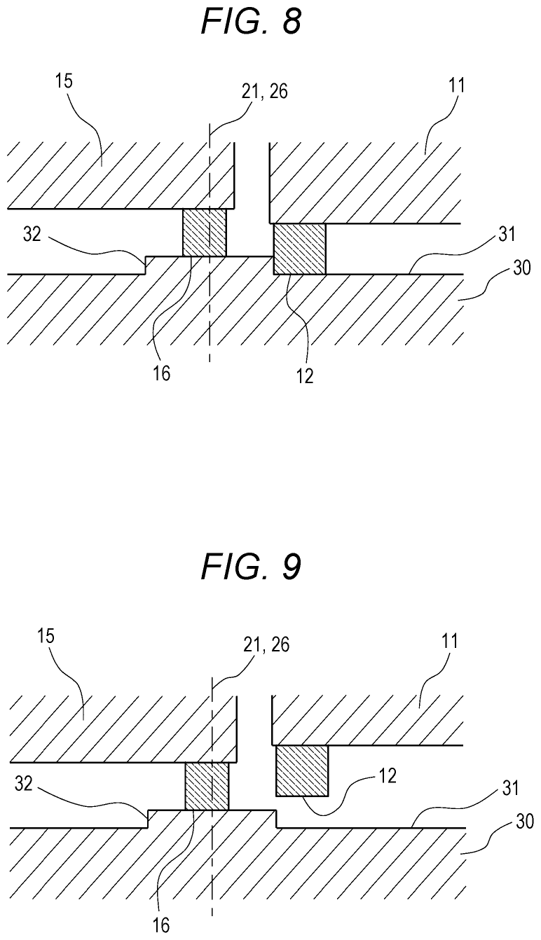

That is, in efficient rough grinding, the entire area of the surface to be processed of the substrate 30 is flattened without leaving the unground protrusion 32 (see FIG. 8) in the vicinity of the rotation center 21 of the substrate 30, and then finish grinding can be performed. The second grinding wheel for performing finish grinding does not need to grind the protrusion 32 left in the vicinity of the rotation center 21 of the substrate 30 as in the substrate grinding device according to the related art. Therefore, it is possible to finish the surface to be processed of the substrate 30 with high accuracy by short-time grinding using the finish grinding wheel 15 having a smaller abrasive grain size than that of the related art.

Further, since the finish grinding wheel 15 does not need to grind the protrusion 32 in the vicinity of the rotation center 21 of the substrate 30, the amount of wear of the finish grinding wheel 15 can be reduced to a small amount. Therefore, the usage of the finish grinding wheel 15 can be reduced, and the production cost of the substrate 30 can be reduced.

Next, a method for producing the substrate by the substrate grinding device 10 will be described in detail.

As illustrated in FIG. 1, first, a chucking step of sucking the substrate 30 onto the rotatable work table 20 is performed.

In the chucking step, the substrate 30 to be processed is placed on the upper surface of the work table 20 on the standby stage 23 by a robot or the like. Then, the attachment housing 22 descends from above the substrate 30, and the substrate 30 is vacuum-sucked by the vacuum chuck of the work table 20.

Then, a conveying step of feeding the work table 20 holding the substrate 30 to the grinding position below the rough grinding wheel 11 and the finish grinding wheel 15 is performed. In the conveying step, the work table 20 holding the substrate 30 moves from the standby stage 23 to the grinding position of the grinding stage 24. Specifically, the work table 20 moves the rotation center 21 of the substrate 30 to the first grinding position 25 (see FIG. 2).

At the grinding stage 24, the grinding step of grinding the substrate 30 is performed. Specifically, when the rotation center 21 of the substrate 30 is located at the first grinding position 25 (see FIG. 2), the first grinding step of grinding the substrate 30 by the rough grinding wheel 11 is performed, and when the rotation center 21 of the substrate 30 is located at the second grinding position 26 (see FIG. 4), the second grinding step of grinding the substrate 30 by the finish grinding wheel 15 is performed. That is, in the first grinding step, the rotation center 21 of the substrate 30 is located at the first grinding position 25, which is a predetermined position within the grinding range of the rough grinding wheel 11. In the second grinding step, the rotation center 21 of the substrate 30 is located at the second grinding position 26, which is a predetermined position within the grinding range of the finish grinding wheel 15.

In the grinding step, first, a thickness of the substrate 30 is measured by the sizing device 28, and the rough grinding wheel 11 is positioned at a position higher than the upper surface 31 (see FIG. 3) of the substrate 30 by an amount of air cut.

In the grinding step, the substrate 30 held on the work table 20 rotates together with the work table 20, and is ground by the rough grinding wheel 11 or the finish grinding wheel 15 that descends while rotating to contact the substrate 30. Note that details of the grinding step will be described below.

The substrate 30 ground by the grinding step moves from the grinding stage 24 to the standby stage 23 together with the work table 20. Then, the vacuum suction of the substrate 30 is released after the grinding step, and the substrate 30 is removed from the work table 20.

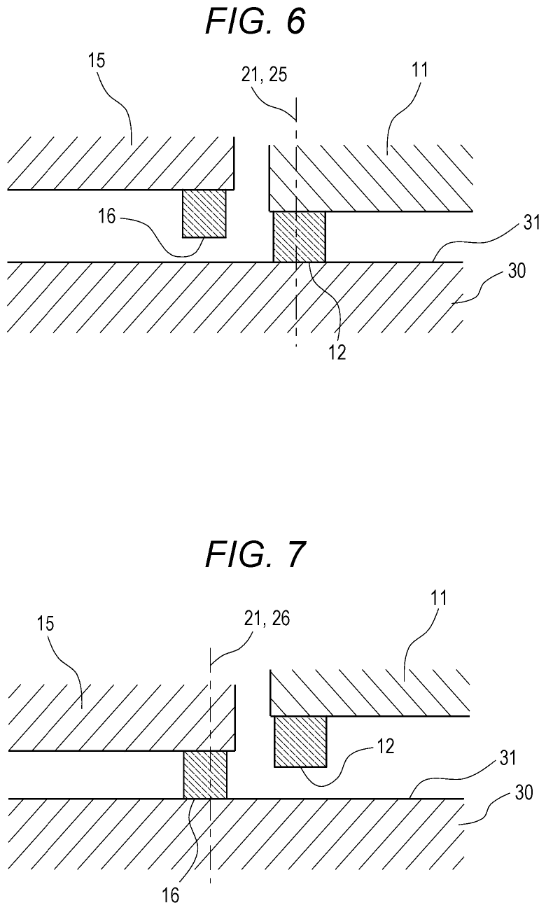

Next, the grinding step of the substrate 30 by the substrate grinding device 10 will be described in detail with reference to FIGS. 6 to 9.

FIG. 6 is a vertical cross-sectional view schematically illustrating the vicinity of the rotation center 21 of the substrate 30 in the rough grinding step.

As illustrated in FIG. 6, in the grinding step, first, the rough grinding step that is the first grinding step is performed. In the rough grinding step, the rotation center 21 of the substrate 30 is located at the first grinding position 25, and the rough grinding wheel 11 approaches the substrate 30 from above to grind the upper surface 31 of the substrate 30.

Specifically, the control panel 27 (see FIG. 1) rotates the work table 20 (see FIG. 3) to rotate the substrate 30 held on the work table 20, and rotates the rough grinding wheel 11 to feed it downward.

Thus, the wheel cutting edge 12 of the rotating rough grinding wheel 11 comes into contact with the upper surface 31 of the substrate 30, which is rotating about the rotation center 21 within the grinding range of the rough grinding wheel 11, and the entire area of the upper surface 31 of the substrate 30 is ground.

A cutting speed of the rough grinding wheel 11 in the rough grinding step is, for example, preferably 10 to 300 μm/min, and more preferably 30 to 300 μm/min. This enables efficient and highly accurate grinding with less wear of the rough grinding wheel 11.

Note that in the rough grinding step, the wheel cutting edge 16 of the finish grinding wheel 15 is above the wheel cutting edge 12 of the rough grinding wheel 11. That is, in the rough grinding step, the wheel cutting edge 16 of the finish grinding wheel 15 is located above and away from the substrate 30 and grinding by the finish grinding wheel 15 is not performed.

As described above, in the rough grinding step, the rotation center 21 of the substrate 30 is within the grinding range of the rough grinding wheel 11, and the entire area of the upper surface 31 including the vicinity of the rotation center 21 of the substrate 30 is efficiently ground by the rough grinding wheel 11 having a large abrasive grain size and less wear.

Next, the finish grinding step that is the second grinding step is performed. In the finish grinding step, after the rough grinding step is performed, first, a position change step is performed in which the work table 20 moves the rotation center 21 of the substrate 30 to the second grinding position 26 below the rough grinding wheel 11 and the finish grinding wheel 15.

In the position change step, as illustrated in FIG. 3, the rough grinding wheel 11 that has finished grinding rises and separates from the upper surface 31 of the substrate 30. That is, the wheel cutting edge 12 of the rough grinding wheel 11 is in a state of being separated from the upper surface 31 of the substrate 30 in substantially the same manner as the wheel cutting edge 16 of the finish grinding wheel 15.

Then, since the work table 20 holding the substrate 30 moves horizontally, the rotation center 21 of the substrate 30 moves to the second grinding position 26 within the grinding range of the finish grinding wheel 15, as illustrated in FIG. 5.

FIG. 7 is a vertical cross-sectional view schematically illustrating the vicinity of the rotation center 21 of the substrate 30 in the finish grinding step.

As illustrated in FIG. 7, in the position change step, the rotation center 21 of the substrate 30 is moved to the second grinding position 26, and then the finish grinding step as the second grinding step is performed. In the finish grinding step, the substrate 30 is ground by the finish grinding wheel 15 which is the second grinding wheel.

Specifically, in a state where the rough grinding wheel 11 does not contact the upper surface 31 of the substrate 30, the control panel 27 (see FIG. 1) controls the work table 20 to rotate and the substrate 30 held on the work table 20 to rotate, and controls the finish grinding wheel 15 to rotate and be fed downward.

Thus, the wheel cutting edge 16 of the rotating finish grinding wheel 15 comes into contact with the upper surface 31 of the substrate 30, which is rotating about the rotation center 21 within the grinding range of the finish grinding wheel 15, and the entire area of the upper surface 31 of the substrate 30 is ground.

A cutting speed of the finish grinding wheel 15 in the finish grinding step is, for example, 5 to 300 μm/min, preferably 5 to 100 μm/min, and more preferably 10 to 100 μm/min. This enables efficient and highly accurate finish grinding with less wear of the finish grinding wheel 15.

As the finish grinding wheel 15, for example, grinding wheels with grain size numbers #4000 to #30000 are used, and preferably grinding wheels with grain size numbers #8000 to #30000 are used, in order to grind the surface to be processed of the substrate 30 with high accuracy. The substrate grinding device 10 grinds the entire area of the upper surface 31 of the substrate 30 by the rough grinding wheel 11 as the first grinding wheel, and then grinds the upper surface 31 of the substrate 30 by the finish grinding wheel 15 as the second grinding wheel.

Therefore, the substrate grinding device 10 can use the grinding wheel having a large grain size number, that is, the grinding wheel having a small abrasive grain size, which is difficult to use as the finish grinding wheel 15 in the related art. This makes it possible to grind the substrate with high accuracy, which is difficult for the substrate grinding device according to the related art, and thus, for example, the large-sized mounting substrate such as the PLP can be flattened efficiently and with high accuracy.

According to the substrate grinding device 10, processing allowance of the finish grinding wheel 15 in the finish grinding step is extremely small, and the amount of wear of the finish grinding wheel 15 is small. Specifically, according to the substrate grinding device 10, the surface to be processed can be flattened more accurately than a grinding method according to the related art in which all grinding steps from rough grinding to finish grinding are performed with one type of grinding wheel. Further, according to the substrate grinding device 10, the grinding time can be reduced to about one half or less and the running cost of the grinding wheel can be reduced to about one quarter or less as compared with the grinding method according to the related art.

FIG. 8 is a vertical cross-sectional view schematically illustrating the vicinity of the rotation center 21 of the substrate 30 in a modification of the second grinding step.

As illustrated in FIG. 8, when the rotation center 21 of the substrate 30 is located at the second grinding position 26, the substrate grinding device 10 can grind the substrate 30 at the same time by the rough grinding wheel 11 and the finish grinding wheel 15. That is, the rough grinding wheel 11 and the finish grinding wheel 15 may be controlled to simultaneously approach the rotating substrate 30 held on the work table 20 while simultaneously rotating, and simultaneously grind the substrate 30.

Specifically, as illustrated in FIG. 6, the first grinding step using only the rough grinding wheel 11 may be performed in a state where the rotation center 21 of the substrate 30 is located at the first grinding position 25, and subsequently the position of the rotation center 21 of the substrate 30 may be changed to the second grinding position 26 in the position change step, and then as illustrated in FIG. 8, a grinding step may be performed using both the rough grinding wheel 11 having a large abrasive grain size for rough grinding and the finish grinding wheel 15 having a small abrasive grain size for finish grinding.

As illustrated in FIG. 8, in the grinding step simultaneously using the rough grinding wheel 11 and the finish grinding wheel 15, in a state where the wheel cutting edge 12 of the rough grinding wheel 11 is closer to the upper surface 31 of the substrate 30 than the wheel cutting edge 16 of the finish grinding wheel 15, that is, in a state where the wheel cutting edge 12 is lower than the wheel cutting edge 16, the rough grinding wheel 11 and the finish grinding wheel 15 approach the substrate 30 and the substrate 30 is ground.

A distance from the wheel cutting edge 16 of the finish grinding wheel 15 to the wheel cutting edge 12 of the rough grinding wheel 11 below is, for example, 1 to 50 μm, and preferably 1 to 30 μm. Note that it is also possible to feed the rough grinding wheel 11 and the finish grinding wheel 15 at the same cutting speed while maintaining a positional relationship therebetween.

In this way, during grinding in a state where the rotation center 21 of the substrate 30 is located at the second grinding position 26, grinding is performed in a state where the rough grinding wheel 11 is closer to the substrate 30 than the finish grinding wheel 15. Thus, the rough grinding wheel 11 having a large abrasive grain size and less wear efficiently grinds the substrate 30 in a wide range excluding the vicinity of the rotation center 21 of the substrate 30.

The finish grinding wheel 15 can grind the entire substrate 30 including the rotation center 21 in the state where the rotation center 21 of the substrate 30 is located at the second grinding position 26. Therefore, by lowering the finish grinding wheel 15 and the rough grinding wheel 11 while rotating them at the same time, the protrusion 32 in the vicinity of the rotation center 21 of the substrate 30, which the rough grinding wheel 11 has not contacted and has not been ground, can be ground by the finish grinding wheel 15.

FIG. 9 is a vertical cross-sectional view schematically illustrating the vicinity of the rotation center of the substrate 30 in the modification of the second grinding step.

After the grinding step using both the rough grinding wheel 11 and the finish grinding wheel 15 illustrated in FIG. 8 is performed, the rough grinding wheel 11 is moved above the finish grinding wheel 15 as illustrated in FIG. 9. That is, the wheel cutting edge 12 of the rough grinding wheel 11 is located above the wheel cutting edge 16 of the finish grinding wheel 15, and is separated from the upper surface 31 of the substrate 30.

Then, in a state where the rough grinding wheel 11 does not contact the upper surface 31 of the substrate 30, the finish grinding wheel 15 contacts the substrate 30 while rotating, and the substrate 30 is ground. Thus, the protrusion 32 in the vicinity of the rotation center 21 of the substrate 30, which the wheel cutting edge 12 of the rough grinding wheel 11 has not contacted and has not been ground, is ground by the finish grinding wheel 15.

As already described with reference to FIG. 6, the upper surface 31 of the substrate 30 is ground by the rough grinding wheel 11 in the first grinding step in the state where the rotation center 21 of the substrate 30 is located at the first grinding position 25. Then, as illustrated in FIGS. 8 and 9, the grinding range of the finish grinding wheel 15 in the second grinding step, which is performed in the state where the rotation center 21 of the substrate 30 is located at the second grinding position 26, is a narrow range in the vicinity of the rotation center 21. Therefore, the amount of wear of the finish grinding wheel 15 can be reduced to a small amount.

After the protrusion 32 is ground by the finish grinding wheel 15 as illustrated in FIG. 9, the grinding of the substrate 30 by the finish grinding wheel 15 is subsequently performed as illustrated in FIG. 7. Then, as described above, the entire area of the upper surface 31 of the substrate 30 is finish-ground and flattened with high accuracy by the wheel cutting edge 16 of the finish grinding wheel 15.

As described above, according to the substrate grinding device and the substrate grinding method according to the embodiment of the present disclosure, efficient grinding can be performed while reducing the number of times the work table 20 is conveyed and reducing the footprint of the device. In addition, it is possible to grind the large-sized mounting substrate or the like efficiently and with high accuracy while reducing an amount of abrasion of the finish grinding wheel 15.

Note that the present disclosure is not limited to the above embodiments, and various modifications can be made without departing from the gist of the present disclosure.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A substrate grinding device comprising:
a work table;
a first grinding wheel; and
a second grinding wheel,
wherein the work table is configured to rotate while sucking and holding a substrate,
the first grinding wheel and the second grinding wheel are cup wheel type wheels, and provided at positions where the first grinding wheel and the second grinding wheel can be simultaneously in contact with the substrate rotating, the first grinding wheel and the second grinding wheel being configured to grind the substrate rotating, while rotating, and
the work table is configured to be able to move a rotation center of the substrate from a first grinding position within a grinding range of the first grinding wheel to a second grinding position within a grinding range of the second grinding wheel.

2. The substrate grinding device according to claim 1, wherein the substrate grinding device is configured such that:
grinding of the substrate by the first grinding wheel is performed in a state where the rotation center of the substrate is located at the first grinding position; and
grinding of the substrate by the second grinding wheel is performed in a state where the rotation center of the substrate is located at the second grinding position.

3. The substrate grinding device according to claim 1, wherein the substrate grinding device is configured to be able to grind the substrate simultaneously by the first grinding wheel and the second grinding wheel in a state where the rotation center of the substrate is located at the second grinding position.

4. A substrate grinding method comprising:
sucking a substrate on a rotatable work table;
moving the work table holding the substrate so that a rotation center of the substrate is located below a cup wheel type first grinding wheel and a cup wheel type second grinding wheel and at a first grinding position within a grinding range of the first grinding wheel;
grinding the substrate while rotating the work table, rotating the substrate held on the work table, and rotating the first grinding wheel, in a state where the rotation center of the substrate is located at the first grinding position;
moving the work table holding the substrate so that the rotation center of the substrate is located below the first grinding wheel and the second grinding wheel and at a second grinding position within a grinding range of the second grinding wheel, after performing grinding by the first grinding wheel; and
grinding the substrate while rotating the work table, rotating the substrate held on the work table, and rotating the second grinding wheel, in a state where the rotation center of the substrate is located at the second grinding position.

5. The substrate grinding method according to claim 4, comprising:
performing grinding by the first grinding wheel, and then moving the work table so that the rotation center of the substrate is located below the first grinding wheel and the second grinding wheel and at the second grinding position within the grinding range of the second grinding wheel;
subsequently grinding the substrate simultaneously by the first grinding wheel and the second grinding wheel while rotating the work table, rotating the substrate held on the work table, and simultaneously rotating the first grinding wheel and the second grinding wheel, in the state where the rotation center of the substrate is located at the second grinding position; and
then further grinding the substrate by the second grinding wheel with the first grinding wheel separated from the substrate.
